(19) United States
(12) Patent Application Publication
(10) Pub. No.: US 2024/0373595 A1
(43) Pub. Date: Nov. 7, 2024

(54) HEAT DISSIPATION SYSTEM AND METHOD FOR DATA CENTER

(71) Applicant: Douyin Vision Co., Ltd., Beijing (CN)

(72) Inventors: Bing GAO, Beijing (CN); Tangbo JING, Beijing (CN); Jian WANG, Beijing (CN)

(21) Appl. No.: 18/289,355

(22) PCT Filed: Nov. 7, 2022
(86) PCT No.: PCT/CN2022/130351

§ 371 Date: Nov. 2, 2023

(30) Foreign Application Priority Data
Nov. 10, 2021 (CN) 202111327466.9

(51) Int. Cl. H05K 7/20

(52) U.S. Cl. CPC H05K 7/20836; H05K 7/20354; H05K 7/20827

(57) ABSTRACT

A heat dissipation system and method for a data center are provided. The heat dissipation system includes a first heat exchanger, a second heat exchanger, a third heat exchanger, and a first controller. The first heat exchanger and the second heat exchanger form a first cooling circuit with a cooling medium outlet and a cooling medium inlet of the data center, and the second heat exchanger and the third heat exchanger form a second cooling circuit. The third heat exchanger is connected to a heat recovery system. The first controller is connected to the first heat exchanger and the second heat exchanger, and is configured to control a heat exchange ratio of the first heat exchanger to the second heat exchanger.

### CROSS REFERENCE TO RELATED APPLICATION

The present application claims priority to Chinese Patent Application No. 202111327466.9, filed on Nov. 10, 2021 and entitled “HEAT DISSIPATION SYSTEM AND METHOD FOR DATA CENTER”, which is incorporated herein by reference in its entirety.

### FIELD

The present disclosure relates to the technical field of heat dissipation for data centers, and in particular, to a heat dissipation system and method for a data center.

### BACKGROUND

With the rapid development of Internet technology, the demand for data centers is increasing, and heat generated by data centers is also increasing, which requires heat dissipation for data centers. Moreover, with the increasing importance of energy conservation and the proposal of the concept of carbon neutrality, people are now no longer limited to the simple need for heat dissipation, but are gradually thinking about heat recovery in the process of heat dissipation.

When the heat recovery technology in the heat dissipation system for a data center in the related art is used for heat recovery, recovered heat cannot adapt to the fluctuations of the recovery capacity of the heat recovery system.

### SUMMARY

The Summary is provided in order to present the concept in a brief form, which will be described in detail hereinafter in the Description of Embodiments. The Summary is not intended to identify key features or essential features of the claimed technical solutions, nor is it intended to limit the scope of the claimed technical solutions.

In a first aspect, the present disclosure provides a heat dissipation system for a data center. The heat dissipation system includes a first heat exchanger, a second heat exchanger, a third heat exchanger, and a first controller. The first heat exchanger and the second heat exchanger form a first cooling circuit with a cooling medium outlet and a cooling medium inlet of the data center, to enable a cooling medium of the data center to sequentially flow through the cooling medium outlet, the first heat exchanger, the second heat exchanger, and the cooling medium inlet, and the first heat exchanger is further configured to perform primary cooling on the cooling medium of the data center. The second heat exchanger and the third heat exchanger form a second cooling circuit, to enable the second heat exchanger to perform secondary cooling on the cooling medium in the first cooling circuit through a cooling medium in the second cooling circuit. The third heat exchanger is connected to a heat recovery system, to enable the third heat exchanger to transfer heat absorbed by the cooling medium in the second cooling circuit to the heat recovery system. The first controller is connected to the first heat exchanger and the second heat exchanger, and is configured to control a heat exchange ratio of the first heat exchanger to the second heat exchanger.

In a second aspect, the present disclosure provides a heat dissipation method for a data center. The heat dissipation method includes: acquiring heat recovery capacity information of a heat recovery system and temperature information of a cooling medium at a cooling medium outlet of the data center; and controlling, by a first controller, a heat exchange ratio of a first heat exchanger to a second heat exchanger based on the heat recovery capacity information and the temperature information.

In the heat dissipation system according to the embodiments of the present disclosure, after heat dissipation is carried out on the data center through the cooling medium of the data center, the cooling medium that has absorbed heat passes through the first heat exchanger and the second heat exchanger sequentially for two times of heat dissipation cooling, thereby achieving a better heat dissipation effect and easily meeting the heat dissipation requirements of the data center. Moreover, the heat dissipation ratio of the two heat dissipation cooling processes is adjustable and controllable, such that when the heat recovery capacity of the heat recovery system fluctuates, by adjusting the heat exchange ratio of the two times of heat dissipation cooling, the normal heat dissipation requirements of the data center may still be met when the heat recovery capacity of the heat recovery system is reduced, and more heat is easily recovered when the heat recovery capacity of the heat recovery system is improved. Therefore, heat recovery that meets the recovery capacity of the heat recovery system can be achieved, the requirements for reliable and continuous heat dissipation of the data center are ensured, and heat recovery can be maximized. In addition, since the heat recovery is performed in the second heat exchanger, the grade of heat energy recovery can be improved. In addition, in the embodiments of the present disclosure, energy saving is achieved by recovering the heat of the cooling medium of the data center, to partially offset the carbon dioxide emissions generated by energy consumption during the operation of the data center, thereby contributing to the carbon neutrality of the data center.

Other features and advantages of the present disclosure will be described in detail in the subsequent detailed description.

### BRIEF DESCRIPTION OF THE DRAWINGS

The above and other features, advantages and aspects of embodiments of the present disclosure will become more apparent in conjunction with the accompanying drawings and with reference to the following specific embodiments. Identical or similar reference signs indicate identical or similar elements throughout the accompanying drawings. It should be understood that the accompanying drawings are schematic and the components and elements are not necessarily drawn in scale.

FIG. 1 is a schematic structural diagram of a heat dissipation system for a data center according to an exemplary embodiment of the present disclosure.

FIG. 2 is a schematic structural diagram of a second heat exchanger according to an exemplary embodiment of the present disclosure.

FIG. 3 is a schematic structural diagram of another heat dissipation system for a data center according to an exemplary embodiment of the present disclosure.

FIG. 4 is a schematic structural diagram of still another heat dissipation system for a data center according to an exemplary embodiment of the present disclosure.

FIG. 5 is a schematic structural diagram of yet still another heat dissipation system for a data center according to an exemplary embodiment of the present disclosure.

FIG. 6 is a flow diagram of a heat dissipation method for a data center according to an exemplary embodiment of the present disclosure.

### REFERENCE SIGNS

10 Data center,
21 Cooling medium outlet of the data center, 22 Cooling medium inlet of the data center,
30 First heat exchanger,
40 Second heat exchanger, 401 Evaporator, 402 Compressor, 403 Condenser, 404 Throttle valve,
50 Third heat exchanger,
60 First controller,
70 Heat recovery system,
80 Cooling tower,
90 Three-way valve, and
100 Phase-change heat storage water tank.

### DESCRIPTION OF EMBODIMENTS

Embodiments of the present disclosure will be described in more detail below with reference to the accompanying drawings. Although some embodiments of the present disclosure are shown in the accompanying drawings, it should be understood that the present disclosure may be implemented in various forms and should not be construed as limitation to the embodiments set forth herein. In contrast, these embodiments are provided for a more thorough and complete understanding of the present disclosure. It should be understood that the accompanying drawings and embodiments of the present disclosure are merely for exemplary purposes and are not intended to limit the scope of the present disclosure.

It should be understood that steps of method embodiments of the present disclosure may be performed in a different order and/or in parallel. In addition, the method embodiments may include additional steps and/or omit the steps illustrated. The scope of the present disclosure is not limited in this regard.

As used herein, the term “include” and variations thereof are open-ended, i.e., “includes, but is not limited to”. The term “based on” is “at least partially based on”. The term “an embodiment” refers to “at least one embodiment”, the term “another embodiment” refers to “at least one additional embodiment”, and the term “some embodiments” refers to “at least some embodiments”. Relevant definitions of other terms will be given in the description below.

It is noted that the concepts mentioned in the present disclosure, such as “first” and “second”, are used merely to distinguish between different apparatuses, modules, or units, and are not intended to define the order or interdependence of the functions performed by these apparatuses, modules, or units.

It is noted that the terms “one” and “a plurality of” mentioned in the present disclosure are illustrative and not restrictive, and it is to be understood by those skilled in the art that they should be understood as “one or more” unless otherwise expressly stated in the context.

The names of messages or information interacted between a plurality of apparatuses in the embodiments of the present disclosure are for illustrative purposes merely and are not intended to limit the scope of these messages or information.

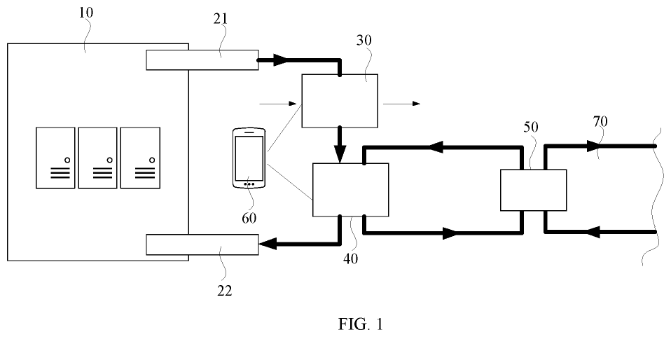

Referring to FIG. 1, FIG. 1 shows a heat dissipation system for a data center according to an exemplary embodiment of the present disclosure. The heat dissipation system may be used for the data center 10, for example, to dissipate heat of a server cabinet in the data center 10. The heat dissipation system includes a first heat exchanger 30, a second heat exchanger 40, a third heat exchanger 50, and a first controller 60.

The first heat exchanger 30 and the second heat exchanger 40 are configured to form a first cooling circuit with a cooling medium outlet 21 of the data center and a cooling medium inlet 22 of the data center. In this way, a cooling medium of the data center flows sequentially through the cooling medium outlet 21 of the data center, the first heat exchanger 30, the second heat exchanger 40, and the cooling medium inlet 22 of the data center, and the first heat exchanger 30 is configured to further perform primary cooling on the cooling medium of the data center. The second heat exchanger 40 and the third heat exchanger 50 form a second cooling circuit, to enable the second heat exchanger 40 to perform secondary cooling on the cooling medium in the first cooling circuit through a cooling medium in the second cooling circuit. The third heat exchanger 50 is configured to be connected to a heat recovery system 70, to enable the third heat exchanger 50 to transfer heat absorbed by the cooling medium in the second cooling circuit to the heat recovery system 70. The first controller 60 is connected to the first heat exchanger 30 and the second heat exchanger 40, and is configured to control a heat exchange ratio of the first heat exchanger 30 to the second heat exchanger 40.

In the embodiments of the present disclosure, the cooling medium of the data center can take away the heat generated by the data center. After flowing out of the cooling medium outlet, the cooling medium passes through the first heat exchanger for the primary heat exchange cooling to obtain a cooling medium of a first temperature. Thereafter the cooling medium of the first temperature passes through the second heat exchanger for the secondary heat exchange cooling to obtain a cooling medium of a second temperature, and the second temperature is lower than the first temperature. That is, heat exchange cooling is performed twice on the cooling medium flowing out of the data center, such that the temperature of the cooling medium flowing out of the data center can reach the usage conditions of the data center after the two heat exchange cooling. The cooling medium of the second temperature is then guided into the data center through the cooling medium inlet 22 of the data center to take away the heat generated by the data center.

During the secondary cooling on the cooling medium of the first temperature, the cooling may be performed with the cooling medium in the second cooling circuit. That is, the cooling medium in the second cooling circuit can exchange heat with the cooling medium of the first temperature to remove heat from the cooling medium of the first temperature, such that after the cooling medium in the second cooling circuit absorbs the heat of the cooling medium of the first temperature, the heat is transferred through the third heat exchanger to be recovered in the heat recovery system.

In addition, in the embodiments of the present disclosure, the first heat exchanger and the second heat exchanger are connected to the first controller, such that the heat exchange ratio of the first heat exchanger to the second heat exchanger can be controlled by the first controller based on actual heat recovery requirements, to achieve heat recovery meeting the recovery capacity of the heat recovery system.

The first controller may be a numerical control console, or a remote control

terminal such as a mobile phone or a remote control.

In the embodiments of the present disclosure, the cooling medium of the data center may be in various forms. In an exemplary embodiment, the cooling medium of the data center may be water or other heat transfer media, such as air.

In an embodiment, the cooling medium of the data center is air. In this case, the cooling medium outlet of the data center is an air outlet, the cooling medium inlet of the data center is an air inlet, and the first heat exchanger is an air-to-air heat exchanger that may include a heat dissipation fan. The first controller is connected to the heat dissipation fan in the air-to-air heat exchanger.

The air-to-air heat exchanger refers to a heat exchanger in which the heat exchange mediums are both air. Since the air-to-air heat exchanger includes the heat dissipation fan, and the first controller is connected to the heat dissipation fan in the air-to-air heat exchanger, the rotational speed of the cooling fan or the air intake volume can be controlled by the first controller to adjust the heat exchange cooling capacity of the air-to-air heat exchanger for air at the air outlet.

It should be understood that the faster the rotational speed of the heat dissipation fan or the higher the air intake volume subsequent to the control by the first controller, the greater the heat exchange cooling capacity of the air-to-air heat exchanger for the air at the air outlet is, more heat the air-to-air heat exchanger can take away, and the less heat the second heat exchanger can take away or absorb. Conversely, the slower the rotational speed of the heat dissipation fan or the lower the air intake volume subsequent to the control by the first controller, the lower the heat exchange cooling capacity of the air-to-air heat exchanger for the air at the air outlet is, the less heat the air-to-air heat exchanger can take away, and the more heat the second heat exchanger can take away or absorb.

In an embodiment, in some scenarios, when in summer, in the early morning or at

other time, the heat recovery demand of the heat recovery system reduces, that is, heat of the heat recovery system taken away by the third heat exchanger is reduced. In this case, heat taken away by the heat exchange cooling of the first heat exchanger can be increased by the first controller and heat taken away by the heat exchange cooling of the second heat exchanger can be appropriately reduced. This can avoid the situation where the temperature of the cooling medium in the second cooling circuit rises due to the reduced heat taken away by the third heat exchanger, which leads to the reduced heat absorbed by the secondary heat exchange cooling and thus may not meet the normal heat dissipation requirements of the data center.

In an embodiment, in other scenarios, when in winter, in the evening or at other time, the heat recovery demand of the heat recovery system increases, that is, heat of the heat recovery system taken away by the third heat exchanger is increased. In this case, heat taken away by the heat exchange cooling of the first heat exchanger can be decreased by the first controller and heat taken away by the heat exchange cooling of the second heat exchanger can be appropriately increased, such that the heat taken away by the heat exchange cooling of the second heat exchanger is increased to allow the heat recovery system to absorb more heat through the third heat exchanger. This can satisfy requirements for more municipal hot water to achieve more heat recovery.

In addition, in some embodiments, when the cooling medium flows into the data center again through the cooling medium inlet, the cooling medium is pre-processed during this process, for example, the cooling medium may be cleaned, dusted, disinfected and the like, so that the cooling medium entering the data center again can meet the normal usage conditions. Still taking the cooling medium being air as an example, the air that has been subjected to the heat exchange cooling may be disinfected, cleaned and the like, such that the air entering the data center again can meet the breathing requirements of staffs in the data center.

After heat dissipation is carried out on the data center through the cooling medium of the data center, the above heat dissipation system allows the cooling medium that has absorbed heat to flow through the first radiator and the second radiator sequentially so as to perform two times of heat dissipation cooling, thereby achieving a better heat dissipation effect and easily meeting the heat dissipation requirements of the data center. Moreover, the heat dissipation ratio of the two heat dissipation cooling processes is adjustable and controllable. Accordingly, when the heat recovery capacity of the heat recovery system fluctuates, by adjusting the heat exchange ratio of the two times of heat dissipation cooling, the normal heat dissipation requirements of the data center can be met even if the heat recovery capacity of the heat recovery system is reduced, and more heat is recovered when the heat recovery capacity of the heat recovery system is improved. Therefore, heat recovery that meets the recovery capacity of the heat recovery system can be achieved, the requirements of the data center for reliable and continuous heat dissipation are ensured and heat recovery is maximized. In addition, since the heat recovery is performed in the second heat exchanger, the grade of heat energy recovery can be improved compared to recovery of heat energy of outside circulating air. Furthermore, in the embodiments of the present disclosure, energy saving is achieved by recovering the heat of the cooling medium of the data center, to partially offset the carbon dioxide emission generated by the energy consumption during the operation of the data center, thereby contributing to the carbon neutrality of the data center.

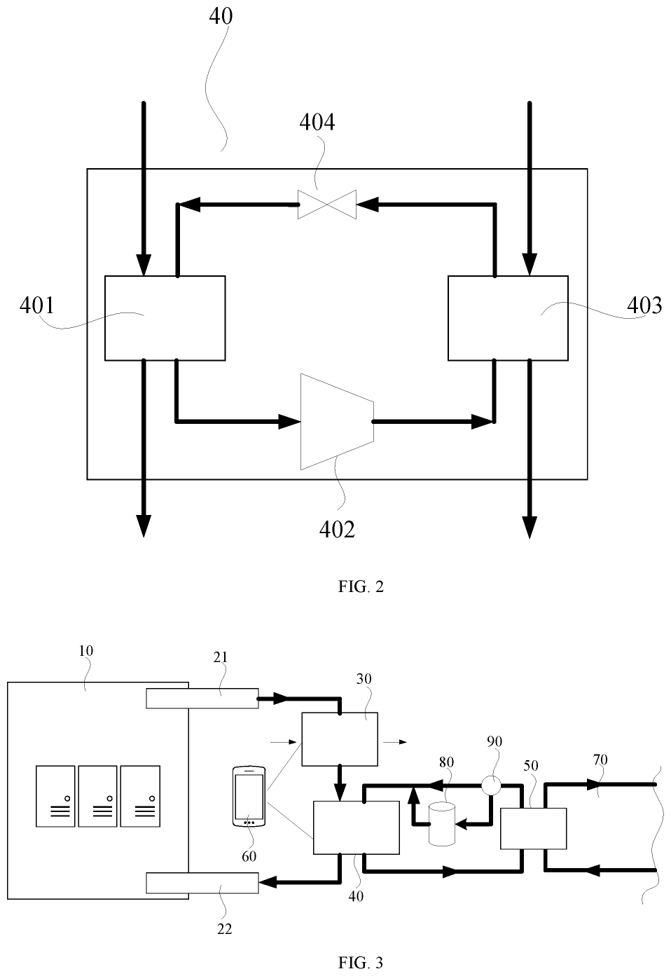

Referring to FIG. 2, in some embodiments, the second heat exchanger 40 includes an evaporator 401, a compressor 402, a condenser 403, and a throttle valve 404. The second cooling circuit includes a third cooling circuit and a fourth cooling circuit. The third cooling circuit is formed by a series connection of the evaporator 401, the compressor 402, the condenser 403, and the throttle valve 404, and the fourth cooling circuit consists of the condenser 403 and the third heat exchanger 50. The first controller 60 is connected to the compressor 402 and/or the throttle valve 404 of the second heat exchanger.

In an embodiment of the present disclosure, the third cooling circuit is a heat absorption and transfer circuit. The heat of the cooling medium of the first temperature is absorbed by a cooling medium in the third cooling circuit, and is transferred to the fourth cooling circuit through the condenser. During the operation of the third cooling circuit, a low-pressure liquid cooling medium in the evaporator takes away the heat of the cooling medium of the first temperature, becomes a high-temperature and high-pressure cooling medium after being pressurized and enthalpically increased by the compressor to flow to the condenser, and the condenser absorbs heat of the high-temperature and high-pressure cooling medium and transfers the heat to the fourth cooling circuit. Meanwhile, the cooling medium becomes a low-temperature and low-pressure cooling medium after passing through the condenser and the throttle valve, to be used for absorbing the heat of the cooling medium of the first temperature again.

The fourth cooling circuit is configured to transfer the absorbed heat to the heat recovery system. During the operation of the fourth cooling circuit, the heat absorbed by the condenser is absorbed by the heat recovery system after flowing through the third heat exchanger along with a cooling medium in the fourth cooling circuit for heat exchange.

In some embodiments, the cooling medium in the fourth cooling circuit is water in order to facilitate the transfer of the absorbed heat and to improve a heat carrying effect during the heat transfer.

In some embodiments, the heat recovery system may be a municipal heating system. After absorbing the heat from the third heat exchanger, the municipal heating system can be used for residential water, industrial water and the like. In addition, the municipal heating system may be used for seasonal heating, for example, to provide heating in late autumn, winter, and early spring. It should be understood that the heat using requirements of the municipal heating system may be variable over time.

Furthermore, in the embodiments of the present disclosure, after the heat exchange ratio of the first heat exchanger to the second controller is controlled by the first controller, the heat exchange amount of the second heat exchanger changes. To accommodate the change of the heat exchange amount, the first controller is configured to be connected to the compressor and/or the throttle of the second heat exchanger, such that the operation of the compressor and/or the throttle valve is controlled by the first controller.

In conjunction with the above embodiments, when the first controller is used to increase the heat taken away by the heat exchange cooling of the first heat exchanger and appropriately decrease the heat taken away by the heat exchange cooling of the second heat exchanger, the first controller controls the compressor to reduce the pressure of a compressed cooling medium, and/or controls the throttle valve to reduce the flow of the cooling medium. When the first controller is used to decrease the heat taken away by the heat exchange cooling of the first heat exchanger and appropriately increase the heat taken away by the heat exchange cooling of the second heat exchanger, the first controller controls the compressor to increase the pressure of the compressed cooling medium, and/or controls the throttle valve to increase the flow of the cooling medium.

In some embodiments, the cooling medium in the third cooling circuit may be a refrigerant. In addition, in order to improve the heat exchange efficiency of the second heat exchanger, the refrigerant may be fluorine, and accordingly, the condenser may be a water-fluorine heat exchanger.

Referring to FIG. 3, in some embodiments, the second cooling circuit further includes a cooling tower 80. The third heat exchanger 50 is configured to selectively turn on a first flow path or a second flow path in the second cooling circuit. The first flow path sequentially passes through the third heat exchanger 50, the cooling tower 80, and the second heat exchanger 40. The second flow path sequentially passes through the third heat exchanger 50 and the second heat exchanger 40.

Based on the above, the heat recovery capacity of the heat recovery system may fluctuate depending on the time, for example, the fluctuate occurs in different seasons or at different time on the same day. The heat exchange system can adapt to the fluctuations to ensure the requirements for continuous and stable heat dissipation of the data center by controlling the heat exchange ratio of the first heat exchanger to the second heat exchanger by the first controller. However, considering that the first heat exchanger and the second heat exchanger are located at a front end of the process of the heat exchange system, if front-end heat dissipation parameters are frequently changed, back-end heat dissipation parameters may be changed accordingly, such that more parameters of the system need to be changed and changes are frequent. Therefore, the way of controlling the heat exchange ratio of the first heat exchanger to the second heat exchanger by the first controller is more suitable for the situation where the heat recovery capacity fluctuates greatly, for example, seasonal control. Therefore, in order to further improve the stability of the heat dissipation system, the cooling tower may be provided in the second cooling circuit. The cooling tower is used to reduce fluctuations of the heat recovery capacity within a short period or small fluctuations of the heat recovery capacity, to further ensure the continuous and stable heat dissipation of the data center.

When the heat recovery capacity of the heat recovery system is low, the heat taken away by the third heat exchanger is decreased such that the temperature of the cooling medium passing through the third heat exchanger is high. If the high-temperature cooling medium is directly used in the second heat exchanger for heat exchange, the heat taken away from the second heat exchanger is decreased such that the temperature of the cooling medium in the second heat exchanger is high. Accordingly, the secondary heat exchange cooling effect of the second heat exchanger for the cooling medium of the first temperature is reduced, which may eventually result in a poor heat dissipation effect on the cooling medium of the data center and may not meet the heat dissipation requirements of the data center. Therefore, the cooling tower is provided to cool the high-temperature cooling medium passing through the third heat exchanger, such that the cooled cooling medium can meet the subsequent heat dissipation requirements of the data center. In this case, a flow path of the cooling medium in the third cooling circuit is the first flow path. That is, the high-temperature cooling medium in the third cooling circuit enters the cooling tower for cooling and dissipating heat after passing through the third heat exchanger, to obtain the low-temperature cooling medium. After that, the low-temperature cooling medium is then transferred to the second heat exchanger to absorb the heat in the second cooling circuit.

When the heat recovery capacity of the heat recovery system meets the requirements, the heat taken away by the third heat exchanger is increased, such that the temperature of the cooling medium passing through the third heat exchanger is relatively low, and the low-temperature cooling medium can be directly used for heat exchange in the second heat exchanger. In this case, a flow path of the cooling medium in the third cooling circuit is the second flow path, that is, the low-temperature cooling medium in the third cooling circuit is directly transferred to the second heat exchanger after passing through the third heat exchanger to absorb the heat in the second cooling circuit.

In some embodiments, the heat dissipation system further includes a second controller and a temperature sensor disposed at an outlet of the third heat exchanger in the second cooling circuit. The second controller is connected to the temperature sensor. The second controller is configured to control the third heat exchanger to turn on the first flow path or the second flow path based on a temperature of the cooling medium in the second cooling circuit detected by the temperature sensor.

It can be understood that the third heat exchanger may be used for heat exchange between two media, such that the third heat exchanger may include two medium outlets, in which one of the two medium outlets is located in the heat recovery system and the other of the two medium outlets is located in the second cooling circuit. In the embodiments of the present disclosure, the temperature sensor is configured to detect the temperature at the outlet of the third heat exchanger in the second cooling circuit.

After the temperature at the outlet of the third heat exchanger in the second cooling circuit is detected, the temperature information is transmitted to the second controller, such that the second controller can control the third heat exchanger to turn on the first flow path or the second flow path based on the temperature information. That is, the second controller can determine whether the temperature of the cooling medium passing through the third heat exchanger meets the requirements based on the temperature information detected by the temperature sensor. If the temperature does not meet the requirements, the cooling medium in the second cooling circuit is a high-temperature cooling medium and the first flow path is turned on. If the temperature meets the requirements, the cooling medium in the second cooling circuit is a low-temperature cooling medium and the second flow path is turned on.

With the above method, the flow path of the cooling medium in the second cooling circuit after passing through the third heat exchanger can be selected automatically through the cooperation of the temperature sensor and the second controller, to avoid manual operation and reduce the difficulty of manual operation caused by time uncertainty and environmental conditions.

In some embodiments, the second controller is specifically configured to: control, when the temperature of the cooling medium in the second cooling circuit detected by the temperature sensor is smaller than a first predetermined threshold, the third heat exchanger to turn on the second flow path; and control, when the temperature of the cooling medium in the second cooling circuit detected by the temperature sensor is greater than or equal to a second predetermined threshold, the third heat exchanger to turn on the first flow path. The second predetermined threshold is greater than or equal to the first predetermined threshold.

For example, if the first predetermined threshold is equal to the second predetermined threshold and is X degrees, when the temperature information detected by the temperature sensor is smaller than X degrees, the second controller can control the third heat exchanger to turn on the second flow path; or when the temperature information detected by the temperature sensor is greater than or equal to X degrees, the second controller can control the third heat exchanger to turn on the first flow path.

For another example, if the first predetermined threshold of M degrees is smaller than the second predetermined threshold of N degrees, when the temperature information detected by the temperature sensor is smaller than M degrees, the second controller can control the third heat exchanger to turn on the second flow path; or when the temperature information detected by the temperature sensor is greater than or equal to N degrees, the second controller can control the third heat exchanger to turn on the first flow path.

In some embodiments, when the first predetermined threshold of M degrees is smaller than the second predetermined threshold of N degrees and the temperature information detected by the temperature sensor is smaller than N degrees and greater than M degrees, it can be determined to specifically control the third heat exchanger to turn on the first flow path or the second flow path based on different ambient temperatures in the operating environment of the system.

For example, in winter, when the cooling medium flows in each cooling circuit, heat dissipated in the cooling circuits is more than that in summer due to the low ambient temperature. Therefore, taking into account the natural heat dissipation in the cooling circuits, when the temperature information detected by the temperature sensor is smaller than N degrees and greater than M degrees in winter, the third heat exchanger is controlled to turn on the second flow path. While in the summer, for example, when the cooling medium flows in the cooling circuits, heat dissipated in the cooling circuits is smaller than that in winter due to the high ambient temperature. Therefore, considering less natural heat dissipation in the cooling circuits, when the temperature information detected by the temperature sensor is smaller than N degrees and greater than M degrees in the summer, the third heat exchanger is controlled to turn on the first flow path. It can be understood that N does not differ much from M under normal circumstances.

In the embodiments of the present disclosure, a buffer temperature interval is set between the first predetermined threshold and the second predetermined threshold to accommodate ambient temperature variations in different seasons, thereby further maintaining the stability of the entire system.

The third heat exchanger can selectively turn on the first flow path or the second flow path in the second cooling circuit in various ways.

In some embodiments, a three-way valve may be used for communication, in which the second cooling circuit further includes a three-way valve. The first flow path sequentially passes through the third heat exchanger, a port A of the three-way valve, a port B of the three-way valve, the cooling tower, and the second heat exchanger. The second flow path sequentially passes through the third heat exchanger, the port A of the three-way valve, a port C of the three-way valve, and the second heat exchanger.

In the embodiments of the present disclosure, the cooling medium in the second cooling circuit passing through the third heat exchanger enters the three-way valve from the port A of the three-way valve. If the first flow path needs to be turned on, the cooling medium flows out from the port B of the three-way valve and then sequentially passes through the cooling tower and the second heat exchanger. If the second flow path needs to be turned on, the cooling medium flows out from the port C of the three-way valve and directly enters the second heat exchanger.

In other embodiments, two parallel switching valves may be used for communication, in which the second cooling circuit of the heat dissipation system further includes a first switching valve and a second switching valve. The first flow path sequentially passes through the third heat exchanger, the first switching valve, the cooling tower, and the second heat exchanger. The second flow path sequentially passes through the third heat exchanger, the second switching valve, and the second heat exchanger.

In the embodiments of the present disclosure, if the first flow path needs to be turned on, the first switching valve is turned on and the second switching valve is turned off, in which the cooling medium in the second cooling circuit that has passed through the third heat exchanger sequentially passes through the first switching valve, the cooling tower, and the second heat exchanger. If the second flow path needs to be turned on, the second switching valve is turned on and the first switching valve is turned off, in which the cooling medium in the second cooling circuit that has passed through the third heat exchanger sequentially passes through the second switch valve and the second heat exchanger.

It is noted that the three-way valve and the switching valves may be controlled by the second controller.

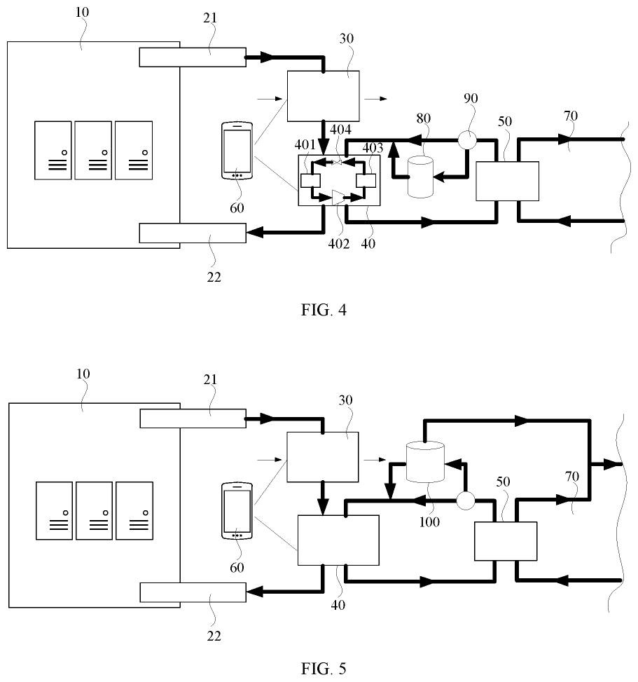

Referring to FIG. 4, it shows another heat dissipation system for the data center 10 according to an exemplary embodiment of the present disclosure. The heat dissipation system includes a first heat exchanger 30, an evaporator 401, a compressor 402, a condenser 403, a throttle valve 404, a third heat exchanger 50, a first controller 60, a second controller, a temperature sensor, and a three-way valve 90.

The first heat exchanger and the second heat exchanger that is composed of the evaporator 401, the compressor 402, the condenser 403 and the throttle valve 404 are configured to form a first cooling circuit with a cooling medium outlet 21 of the data center and a cooling medium inlet 22 of the data center.

The evaporator 401, the compressor 402, the condenser 403 and the throttle valve 404 are connected in series to form a third cooling circuit.

The condenser 403 and the third heat exchanger 50 are configured to form a fourth cooling circuit. A cooling tower 80 may be provided in the fourth cooling circuit. The three-way valve 90 is disposed between the cooling tower 80 and the third heat exchanger 50. The third heat exchanger 50 is provided with the temperature sensor at an outlet of the fourth cooling circuit.

The third heat exchanger 50 is connected to a heat recovery system. The first controller 60 is connected to the compressor 402, the throttle valve 404, and a heat dissipation fan of the first heat exchanger 30.

The detailed description of the structure of each part in FIG. 4 is referred to the relevant parts of the above embodiments, which will not be repeated herein.

Referring to FIG. 5, in some embodiments, the second cooling circuit further includes a phase-change heat storage water tank 100. The third heat exchanger 50 is configured to selectively turn on a third flow path or a second flow path in the second cooling circuit. The third flow path sequentially passes through the third heat exchanger 50, the phase-change heat storage water tank 100, and the second heat exchanger 40. The second flow path sequentially passes through the third heat exchanger 50 and the second heat exchanger 40. The phase-change heat storage water tank 100 is connected to the heat recovery system 70.

The phase-change heat storage water tank 100 is configured to absorb and store the heat of the cooling medium in the second cooling circuit by phase change of an internal medium.

Based on the above, the heat recovery capacity of the heat recovery system may fluctuate depending on time, for example, fluctuate at different time on the same day. In addition, although the overall heat dissipation requirements of the data center are stable, there may still be some differences at different moments of the day. For example, the heat dissipation requirement in a non-working period at night is lower than the heat dissipation requirement in the working period in the daytime, resulting in some fluctuations in the heat generated by the data center. However, the fluctuations of the heat recovery capacity are not completely consistent with the fluctuations of the heat generated by the data center, and there is a time difference therebetween. That is, in a day, a period when the data center generates more heat (i.e., the working period in the daytime) and a period when the heat recovery system uses more heat (i.e., in the evening, in the morning or the like) do not coincide. That is, in some periods, the heat generated by the data center is still residual after the heat is transferred to the heat recovery system, and in other periods, the heat generated by the data center may be insufficient when the heat is transferred to the heat recovery system. Therefore, in order to further meet the requirements for stable heat dissipation of the data center and the usage requirements for stable heat recovery of the heat recovery system, the phase-change heat storage water tank may be provided in the second cooling circuit. The phase-change heat storage water tank is configured to store the excess heat during the daytime and the like, and provide the stored excess heat to the heat recovery system when smaller heat is generated in the evening or in the morning, to balance the fluctuations of the heat recovery capacity within a short period and the fluctuations of the heat generated by the data center, thereby further ensuring the continuous and stable heat dissipation of the data center and meeting the actual heat recovery requirements of the heat recovery system over time.

Thus, in the embodiments of the present disclosure, the excess heat is temporarily stored such that the reuse of the excess heat at different periods can be further achieved compared to the situation dissipating the heat to the environment through the cooling tower. In this way, the heat recovery effect is further improved, which further contributes to achieving the carbon neutrality of the data center.

In addition, in some embodiments, the detailed implementation for the third heat exchanger to selectively turn on the third flow path or the second flow path in the second cooling circuit is referred to the above detailed implementation for the third heat exchanger to selectively turn on the first flow path or the second flow path in the second cooling circuit.

That is, in the case that the cooling tower is replaced with the phase-change heat storage water tank, in some embodiments, the heat dissipation system may also include the second controller and the temperature sensor that is disposed at the outlet of the third heat exchanger in the second cooling circuit, and the second controller is connected to the temperature sensor.

In other embodiments, the second cooling circuit may also include a three-way valve. The third flow path sequentially passes through the third heat exchanger, a port A of the three-way valve, a port B of the three-way valve, the phase-change heat storage water tank, and the second heat exchanger. The second flow path sequentially passes through the third heat exchanger, the port A of the three-way valve, a port C of the three-way valve, and the second heat exchanger. In still other embodiments, the second cooling circuit may also include a first switching valve and a second switching valve. The third flow path sequentially passes through the third heat exchanger, the first switching valve, the phase-change heat storage water tank, and the second heat exchanger. The second flow path sequentially passes through the third heat exchanger, the second switching valve, and the second heat exchanger.

The detailed working principle of the above structure is referred to the detailed implementation for the third heat exchanger to selectively turn on the first flow path or the second flow path in the second cooling circuit, which will not be described herein.

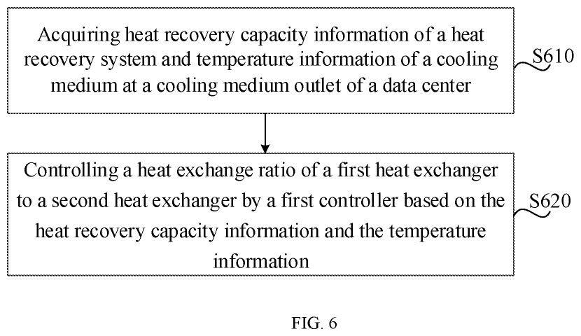

Referring FIG. 6, it is a flow diagram of a heat dissipation method for a data center according to an exemplary embodiment of the present disclosure. The heat dissipation method may be applied to the heat dissipation system according to any one of the above embodiments. Referring to FIG. 6, the heat dissipation method for the data center includes actions at blocks S610 and S620.

At block S610, heat recovery capacity information of the heat recovery system and temperature information of a cooling medium is acquired at the cooling medium outlet of the data center.

At blocks S620, a heat exchange ratio of the first heat exchanger to the second heat exchanger is controlled by the first controller based on the heat recovery capacity information and the temperature information.

The heat recovery capacity information may indicate heat information required by the heat recovery system, and the temperature information of the cooling medium at the cooling medium outlet of the data center may indicate total heat information generated by the data center. Therefore, after the heat information required by the heat recovery system and the total heat information are obtained, the heat exchange ratio of the first heat exchanger to the second heat exchanger can be controlled by the first controller.

In an embodiment, assuming that the total heat information is 10 units of heat, and the heat information required by the heat recovery system is 4 units of heat, the first controller controls the heat exchange ratio of the first heat exchanger to the second heat exchanger to be 6:4. That is, heat exchanged by the first heat exchanger is 6 units of heat, and heat that is transferred to the heat recovery system through the second heat exchanger is 4 units of heat.

The heat recovery capacity information may be roughly determined based on a corresponding table of time versus predetermined heat recovery capacity information, or may be determined based on heat recovery capacity information reported by the heat recovery system.

According to one or more embodiments of the present disclosure, Example 1 provides a heat dissipation system for a data center. The heat dissipation system includes a first heat exchanger, a second heat exchanger, a third heat exchanger, and a first controller.

The first heat exchanger and the second heat exchanger are configured to form a first cooling circuit with a cooling medium outlet and a cooling medium inlet of the data center, to enable a cooling medium of the data center to sequentially flow through the cooling medium outlet, the first heat exchanger, the second heat exchanger, and the cooling medium inlet, and the first heat exchanger is further configured to perform primary cooling on the cooling medium of the data center.

The second heat exchanger and the third heat exchanger are configured to form a second cooling circuit, to enable the second heat exchanger to perform secondary cooling on the cooling medium in the first cooling circuit based on a cooling medium in the second cooling circuit.

The third heat exchanger is connected to a heat recovery system, to enable the third heat exchanger to transfer heat absorbed by the cooling medium in the second cooling circuit to the heat recovery system.

The first controller is connected to the first heat exchanger and the second heat exchanger, and is configured to control a heat exchange ratio of the first heat exchanger to the second heat exchanger.

According to one or more embodiments of the present disclosure, Example 2 provides the heat dissipation system of Example 1. The second heat exchanger includes an evaporator, a compressor, a condenser, and a throttle valve. The second cooling circuit includes a third cooling circuit and a fourth cooling circuit, the third cooling circuit is formed by a series connection of the evaporator, the compressor, the condenser, and the throttle valve, and the fourth cooling circuit is composed of the condenser and the third heat exchanger.

The first controller is connected to the compressor and/or the throttle valve in the

second heat exchanger.

According to one or more embodiments of the present disclosure, Example 3 provides the heat dissipation system of Example 2. The heat recovery system includes a municipal heating system, and a cooling medium in the fourth cooling circuit is water.

According to one or more embodiments of the present disclosure, Example 4 provides the heat dissipation system of Example 1. The cooling medium outlet of the data center is an air outlet, the cooling medium inlet of the data center is an air inlet, and the first heat exchanger is an air-to-air heat exchanger that includes a heat dissipation fan. The first controller is connected to the heat dissipation fan in the air-to-air heat exchanger.

According to one or more embodiments of the present disclosure, Example 5 provides the heat dissipation system of Example 1. The second cooling circuit further includes a cooling tower, and the third heat exchanger is configured to selectively turn on a first flow path or a second flow path in the second cooling circuit. The first flow path sequentially passes through the third heat exchanger, the cooling tower, and the second heat exchanger, and the second flow path sequentially passes through the third heat exchanger and the second heat exchanger.

According to one or more embodiments of the present disclosure, Example 6 provides the heat dissipation system of Example 5. The heat dissipation system further includes a second controller and a temperature sensor that is disposed at an outlet of the third heat exchanger in the second cooling circuit, and the second controller is connected to the temperature sensor.

The second controller is configured to control, based on a temperature of the cooling medium in the second cooling circuit detected by the temperature sensor, the third heat exchanger to turn on the first flow path or the second flow path.

According to one or more embodiments of the present disclosure, Example 7 provides the heat dissipation system of Example 6. The second controller is configured to: control the third heat exchanger to turn on the second flow path when the temperature of the cooling medium in the second cooling circuit detected by the temperature sensor is smaller than a first predetermined threshold; and control the third heat exchanger to turn on the first flow path when the temperature of the cooling medium in the second cooling circuit detected by the temperature sensor is greater than or equal to a second predetermined threshold. The second predetermined threshold is greater than or equal to the first predetermined threshold.

According to one or more embodiments of the present disclosure, Example 8 provides the heat dissipation system of Example 5. The second cooling circuit further includes a three-way valve. The first flow path sequentially passes through the third heat exchanger, a port A of the three-way valve, a port B of the three-way valve, the cooling tower, and the second heat exchanger, and the second flow path sequentially passes through the third heat exchanger, the port A of the three-way valve, a port C of the three-way valve, and the second heat exchanger.

According to one or more embodiments of the present disclosure, Example 9 provides the heat dissipation system of Example 5. The second cooling circuit further includes a first switching valve and a second switching valve. The first flow path sequentially passes through the third heat exchanger, the first switching valve, the cooling tower, and the second heat exchanger, and the second flow path sequentially passes through the third heat exchanger, the second switching valve, and the second heat exchanger.

According to one or more embodiments of the present disclosure, Example 10 provides the heat dissipation system of Example 1. The second cooling circuit further includes a phase-change heat storage water tank. The third heat exchanger is configured to selectively turn on a third flow path or the second flow path in the second cooling circuit. The third flow path sequentially passes through the third heat exchanger, the phase-change heat storage water tank, and the second heat exchanger, the second flow path sequentially passes through the third heat exchanger and the second heat exchanger, and the phase-change heat storage water tank is connected to the heat recovery system.

According to one or more embodiments of the present disclosure, Example 11 provides a heat dissipation method for a data center. The heat dissipation method is applied to the heat dissipation system according to any one of Examples 1 to 10, and includes: acquiring heat recovery capacity information of the heat recovery system and temperature information of a cooling medium at the cooling medium outlet of the data center; and controlling, by the first controller, a heat exchange ratio of a first heat exchanger to a second heat exchanger based on the heat recovery capacity information and the temperature information.

The above description is merely preferred embodiments of the present disclosure and a description of the technical principles applied. It should be understood by those skilled in the art that the scope of the disclosure covered by the present disclosure is not limited to the technical solutions formed by specific combinations of the above features, but should also cover other technical solutions formed by any combination of the above features or their equivalent features without departing from the above disclosed concept, for example, technical solutions formed by substituting the above features with technical features having similar functions disclosed (but not limited to) in the present disclosure.

In addition, while the structures and operations are depicted in a particular order, it is not to be construed as requiring that the operations be performed in the particular order indicated or in a sequential order. Multitasking and parallel processing may be advantageous in certain environments. Similarly, while a plurality of specific implementation details is included in the above discussion, these should not be construed as limiting the scope of the present disclosure. Certain features described in the context of separate embodiments may also be implemented in combination in a single embodiment. Conversely, the various features described in the context of a single embodiment may also be implemented in a plurality of embodiments individually or in any suitable sub-combination.

Although the present subject matter has been described using description specific to structural features and/or method logical actions, it should be understood that the subject matter as defined in the appended claims is not necessarily limited to the particular features or actions described above. Rather, the particular features and actions described above are merely exemplary forms to implement the claims. As for the method in the above embodiments, the specific manner in which operations are performed has been described in detail in the structure embodiments, which is thus not described in detail herein.

1. A heat dissipation system for a data center, the heat dissipation system comprising a first heat exchanger, a second heat exchanger, a third heat exchanger, and a first controller,
wherein the first heat exchanger and the second heat exchanger form a first cooling circuit with a cooling medium outlet and a cooling medium inlet of the data center, to enable a cooling medium of the data center to sequentially flow through the cooling medium outlet, the first heat exchanger, the second heat exchanger, and the cooling medium inlet, and the first heat exchanger is further configured to perform primary cooling on the cooling medium of the data center;
wherein the second heat exchanger and the third heat exchanger form a second cooling circuit, to enable the second heat exchanger to perform secondary cooling on the cooling medium in the first cooling circuit through a cooling medium in the second cooling circuit;
wherein the third heat exchanger is connected to a heat recovery system, to enable the third heat exchanger to transfer heat absorbed by the cooling medium in the second cooling circuit to the heat recovery system; and
wherein the first controller is connected to the first heat exchanger and the second heat exchanger, and is configured to control a heat exchange ratio of the first heat exchanger to the second heat exchanger.

2. The heat dissipation system according to claim 1, wherein:
the second heat exchanger comprises an evaporator, a compressor, a condenser, and a throttle valve;
the second cooling circuit comprises a third cooling circuit and a fourth cooling circuit, the third cooling circuit being formed by a series connection of the evaporator, the compressor, the condenser, and the throttle valve, and the fourth cooling circuit being formed by the condenser and the third heat exchanger; and
the first controller is connected to the compressor and/or the throttle valve of the second heat exchanger.

3. The heat dissipation system according to claim 2, wherein:
the heat recovery system comprises a municipal heating system; and
a cooling medium in the fourth cooling circuit is water.

4. The heat dissipation system according to claim 1, wherein:
the cooling medium outlet of the data center is an air outlet;
the cooling medium inlet of the data center is an air inlet;
the first heat exchanger is an air-to-air heat exchanger comprising a heat dissipation fan; and
the first controller is connected to the heat dissipation fan of the air-to-air heat exchanger.

5. The heat dissipation system according to claim 1, wherein:
the second cooling circuit further comprises a cooling tower; and
the third heat exchanger is configured to selectively turn on a first flow path or a second flow path in the second cooling circuit, the first flow path sequentially passing through the third heat exchanger, the cooling tower, and the second heat exchanger, and the second flow path sequentially passing through the third heat exchanger and the second heat exchanger.

6. The heat dissipation system according to claim 5, further comprising:
a second controller; and
a temperature sensor provided at an outlet of the third heat exchanger in the second cooling circuit, the second controller being connected to the temperature sensor,
wherein the second controller is configured to control, based on a temperature of the cooling medium in the second cooling circuit that is detected by the temperature sensor, the third heat exchanger to turn on the first flow path or the second flow path.

7. The heat dissipation system according to claim 6, wherein the second controller is configured to:
control, when the temperature of the cooling medium in the second cooling circuit that is detected by the temperature sensor is smaller than a first predetermined threshold, the third heat exchanger to turn on the second flow path; and
control, when the temperature of the cooling medium in the second cooling circuit that is detected by the temperature sensor is greater than or equal to a second predetermined threshold, the third heat exchanger to turn on the first flow path, the second predetermined threshold being greater than or equal to the first predetermined threshold.

8. The heat dissipation system according to claim 5, wherein the second cooling circuit further comprises a three-way valve, the first flow path sequentially passing through the third heat exchanger, a port A of the three-way valve, a port B of the three-way valve, the cooling tower, and the second heat exchanger, and the second flow path sequentially passing through the third heat exchanger, the port A of the three-way valve, a port C of the three-way valve, and the second heat exchanger.

9. The heat dissipation system according to claim 5, wherein the second cooling circuit further comprises a first switching valve and a second switching valve, the first flow path sequentially passing through the third heat exchanger, the first switching valve, the cooling tower, and the second heat exchanger, and the second flow path sequentially passing through the third heat exchanger, the second switching valve, and the second heat exchanger.

10. The heat dissipation system according to claim 1, wherein:
the second cooling circuit further comprises a phase-change heat storage water tank;
the third heat exchanger is configured to selectively turn on a third flow path or a second flow path in the second cooling circuit, the third flow path sequentially passing through the third heat exchanger, the phase-change heat storage water tank, and the second heat exchanger, and the second flow path sequentially passing through the third heat exchanger and the second heat exchanger; and
the phase-change heat storage water tank is connected to the heat recovery system.

11. A heat dissipation method for a data center, the heat dissipation method being applied to the heat dissipation system according to claim 1, the heat dissipation method comprising:
acquiring heat recovery capacity information of the heat recovery system and temperature information of a cooling medium at the cooling medium outlet of the data center; and
controlling, by the first controller, a heat exchange ratio of a first heat exchanger to a second heat exchanger based on the heat recovery capacity information and the temperature information.

12. The heat dissipation method according to claim 11, wherein:
the second heat exchanger comprises an evaporator, a compressor, a condenser, and a throttle valve;
the second cooling circuit comprises a third cooling circuit and a fourth cooling circuit, the third cooling circuit being formed by a series connection of the evaporator, the compressor, the condenser, and the throttle valve, and the fourth cooling circuit being formed by the condenser and the third heat exchanger; and
the first controller is connected to the compressor and/or the throttle valve of the second heat exchanger.

13. The heat dissipation method according to claim 12, wherein:
the heat recovery system comprises a municipal heating system; and
a cooling medium in the fourth cooling circuit is water.

14. The heat dissipation method according to claim 11, wherein:
the cooling medium outlet of the data center is an air outlet;
the cooling medium inlet of the data center is an air inlet;
the first heat exchanger is an air-to-air heat exchanger comprising a heat dissipation fan; and
the first controller is connected to the heat dissipation fan of the air-to-air heat exchanger.

15. The heat dissipation method according to claim 11, wherein:
the second cooling circuit further comprises a cooling tower; and
the third heat exchanger is configured to selectively turn on a first flow path or a second flow path in the second cooling circuit, the first flow path sequentially passing through the third heat exchanger, the cooling tower, and the second heat exchanger, and the second flow path sequentially passing through the third heat exchanger and the second heat exchanger.

16. The heat dissipation method according to claim 15, wherein the heat dissipation system further comprises:
a second controller; and
a temperature sensor provided at an outlet of the third heat exchanger in the second cooling circuit, the second controller being connected to the temperature sensor,
wherein the second controller is configured to control, based on a temperature of the cooling medium in the second cooling circuit that is detected by the temperature sensor, the third heat exchanger to turn on the first flow path or the second flow path.

17. The heat dissipation method according to claim 16, wherein the second controller is configured to:
control, when the temperature of the cooling medium in the second cooling circuit that is detected by the temperature sensor is smaller than a first predetermined threshold, the third heat exchanger to turn on the second flow path; and
control, when the temperature of the cooling medium in the second cooling circuit that is detected by the temperature sensor is greater than or equal to a second predetermined threshold, the third heat exchanger to turn on the first flow path, the second predetermined threshold being greater than or equal to the first predetermined threshold.

18. The heat dissipation method according to claim 15, wherein the second cooling circuit further comprises a three-way valve, the first flow path sequentially passing through the third heat exchanger, a port A of the three-way valve, a port B of the three-way valve, the cooling tower, and the second heat exchanger, and the second flow path sequentially passing through the third heat exchanger, the port A of the three-way valve, a port C of the three-way valve, and the second heat exchanger.

19. The heat dissipation method according to claim 15, wherein the second cooling circuit further comprises a first switching valve and a second switching valve, the first flow path sequentially passing through the third heat exchanger, the first switching valve, the cooling tower, and the second heat exchanger, and the second flow path sequentially passing through the third heat exchanger, the second switching valve, and the second heat exchanger.

20. The heat dissipation method according to claim 11, wherein:
the second cooling circuit further comprises a phase-change heat storage water tank;
the third heat exchanger is configured to selectively turn on a third flow path or a second flow path in the second cooling circuit, the third flow path sequentially passing through the third heat exchanger, the phase-change heat storage water tank, and the second heat exchanger, and the second flow path sequentially passing through the third heat exchanger and the second heat exchanger; and
the phase-change heat storage water tank is connected to the heat recovery system.
